(19) United States
(12) Patent Application Publication
(10) Pub. No.: US 2012/0068698 A1
(43) Pub. Date: Mar. 22, 2012

(54) STRUCTURE OF TMR AND FABRICATION METHOD OF INTEGRATED 3-AXIS MAGNETIC FIELD SENSOR AND SENSING CIRCUIT

(75) Inventors: Young-Shying Chen, Hsinchu City (TW); Cheng-Tyng Yen, Kaohsiung City (TW)

(73) Assignee: INDUSTRIAL TECHNOLOGY RESEARCH INSTITUTE, Hsinchu (TW)

(21) Appl. No.: 13/097,083

(22) Filed: Apr. 29, 2011

Related U.S. Application Data
(60) Provisional application No. 61/383,734, filed on Sep. 17, 2010.

(51) Int. Cl. G01R 33/02; H01L 43/12; H01L 29/82

(52) U.S. Cl. 324/252; 257/427; 438/3; 257/E29.323; 257/E43.006

(57) ABSTRACT

A structure of TMR includes two magnetic tunneling junction (MTJ) devices with the same pattern and same magnetic film stack on a same conducting bottom electrode and a parallel connection of conducting top electrode. Each MTJ device includes a pinned layer on the bottom electrode, having a pinned magnetization; a non-magnetic tunneling on the pinned layer; and a free layer on the tunneling layer, having a free magnetization. These two MTJ devices have a collinear of easy-axis and their pinned magnetizations all are parallel to a same pinned direction which has an angle of 45 degree to easy-axis; their free magnetizations initially are parallel to the easy-axis but directions are mutual anti-parallel by applying a current generated ampere field. The magnetic field sensing direction is perpendicular to the easy-axis on the substrate.

### CROSS-REFERENCE TO RELATED APPLICATION

This application claims the priority benefits of U.S. provisional application Ser. No. 61/383,734, filed on Sep. 17, 2010. The entirety of the above-mentioned patent applications is hereby incorporated by reference herein and made a part of this specification.

### TECHNICAL FIELD

The disclosure relates to a magnetic field sensing apparatus, more particularly, to a single chip of integrated 3-axis magnetic field sensor could serve as electronic compass.

### BACKGROUND

The electronic compass has being integrated in various electronic products to improve performance. For example, the electronic compass can be used in the GPS to improve sensation. The heading direction in the GPS is determined by movement of object. However, when the speed is slow or even at the static position, the GPS cannot precisely determine the orientation. The electronic compass can provide the information of the azimuth angle to aid the direction.

The mechanism for sensing magnetic field has been proposed in various manners, such as typical Hall device or magneto-resistive devices. Magneto-resistive devices including anisotropic magneto-resistor (AMR), giant magneto-resistor (GMR) and tunneling magneto-resistor (TMR) have the benefits of larger sensitivity than Hall device, and back-end process of them are also easy to integrate with front-end process of CMOS.

The AMR magnetic field sensor is already commercialized, but only limited to at most 2-axis integrated type of chip. The GMR has larger magneto-resistance ratio (MR) than AMR, however unlike the AMR, can be easy to make 45 degree of shorting bars, so called Barber pole bias, to operate at bipolar mode. The GMR is difficult to operate at bipolar mode and can only be at unipolar mode to sense the magnitude of magnetic field. Recently, the reality of high MR TMR is more attractive and only few products of single axis of magnetic field sensor have been vended. Unexpectedly, the TMR structure and magnetic thin film property limit the feasibility of multi-axis magnetic field sensor instead.

A typical TMR for magnetic field sensor 95 is shown in FIGS. 1A-1B, including a bottom plate of conducting metal, servings as a bottom electrode 102 formed on a substrate 90, a MTJ (Magnetic Tunneling Junction) device 110 formed on the bottom electrode 102 and a top plate of conducting material, serving as a top electrode 106 formed on the MTJ device 110. From the structure pattern of a MTJ device, one can define a cross having intersection at the center, the longer length is called major axis 101 and the shorter length is called minor axis 103, and also a line called easy-axis 180 is collinear with major axis 101. The MTJ device 110 includes a pinned layer 112, a tunneling layer 115 and a free layer 116, in which the MTJ device 110 is sandwiched between the bottom electrode 102 and the top electrode 106, for example. The pinned layer 112 is made of magnetic material formed on the bottom electrode 102 and has a first pinned magnetization 114, being parallel to a pinned direction. The tunneling layer 115 of non-magnetic material is formed on the pinned layer 112. The free layer 116 of magnetic material is formed on the tunneling layer 115 and has a first free magnetization 118, being initially parallel to the easy axis 180.

After the MTJ device is formed (i.e. magnetic thin film stacking and pattern etching), the pinned direction is set by applying a field during anneal process. After anneal process, the pinned direction will be parallel to the direction of the applied field, and the free magnetization is tending to be parallel to the easy-axis due to the shape anisotropy. Therefore, the magnetic field sensing direction of the TMR is perpendicularly to the easy-axis 180 after annealing process. Additionally, the magnetic film typically is material of horizontal polarization and suffers a very strong demagnetization field to confine the activities of magnetizations of free and pinned layers, all of which are in-plane of the magnetic film. Namely, the free magnetization is easy to rotate on the horizontal plane but hardly stands perpendicular to the plane of the magnetic film. Consequently, typical structure of TMR is only available for single axis magnetic field sensor.

Through AMR or even GMR, it can achieve an integrated 2-axis magnetic field sensor, but the footprint sizes of them are quite large. Because of their very low resistivity, the device length has to be longer enough to a usable value for sensing field. FIGS. 2A-2B are drawings, schematically illustrating a Wheatstone bridge circuit without and with shielding. As shown in FIG. 2A, the Wheatstone bridge circuit is the popular adopted method to transfer the sensed magnetic field into electronic signal. For the AMR magnetic sensor, each element R11, R21, R12, R22 of the bridge is a series connection of several Barber pole biased AMRs and the shorting bar angles of any adjacent elements are complementary, so that the bridge is symmetric and full range operation. However, for the GMR or TMR magnetic field sensor, due to their symmetric behavior of magnetic field, two elements R21, R12 therefore must be shield, as shown in FIG. 2B, to be asymmetric and it only uses half range operation. For higher MR of TMR, the asymmetric half range operation results in the bridge output losing linearity and accuracy.

Due to the magnetic film prosperities as mentioned above, for sensing the magnetic field with direction is perpendicular to the substrate by using magneto-resistor, a bevel of incline is necessary to sense the component of the perpendicular field on the incline. The challenges of AMR are that it requires large area of incline and the 45 degree shorting bar is a problem for lithography and etch process. So far as the typical TMR is concerned, the multi-directional of pinned direction setting is still a barrier.

The application of electronic compass generally needs to sense the components of geo-magnetic field at X-Y-Z directions. So far as, the conventional electronic compass chip usually packaged three individual magnetic field sensors to separately sense the each directional components of the geo-magnetic field. How to design a 3-axis integrated and low cost magnetic field sensor is still an issue in the art.

### SUMMARY

The disclosure proposes a structure of TMR (Tunneling Magneto-Resistor) to sense magnetic field and fabrication method to form a 3-axis TMR magnetic field sensor on a substrate, simultaneously.

In an embodiment of disclosure, a magnetic field sensing structure of TMR comprises a bottom electrode, a first MTJ device, a second MTJ device, and a top electrode. The first MTJ device comprises a first pinned layer on the bottom electrode, having a first pinned magnetization at a pinned direction; a first tunneling layer, disposed on the first pinned layer; and a first magnetic free layer, disposed on the first tunneling layer, having a first free magnetization parallel to an easy axis and an included angle formed between the pinned direction and the easy axis. The second MTJ device with an identical structure to the first MTJ device comprises a second pinned layer on the bottom electrode, having a second pinned magnetization at the pinned direction; a second tunneling layer, disposed on the second pinned layer; and a second magnetic free layer, disposed on the second tunneling layer, having a second free magnetization parallel to the easy axis. The top electrode connects the first magnetic free layer and the second magnetic free layer. The first free magnetization and the second free magnetization at an initial state are parallel to the easy axis but mutual anti-parallel. The included angle between the pinned direction and the easy axis is substantially 45 or 135 degrees.

In an embodiment of disclosure, an in-plane magnetic field sensor comprises a substrate, a magnetic sensing structure of TMR and a metal line route. The magnetic sensing structure of TMR comprises a bottom electrode on the substrate, a first MTJ device, a second MTJ device, a top electrode. The first MTJ device comprises: a first pinned layer on the bottom electrode, having a first pinned magnetization at a pinned direction; a first tunneling layer disposed on the first pinned layer; and a first magnetic free layer disposed on the first tunneling layer, having a first free magnetization parallel to an easy axis and an included angle formed between the pinned direction and the easy axis. The second MTJ device with an identical structure to the first MTJ device comprises a second pinned layer on the bottom electrode, having a second pinned magnetization at the pinned direction; a second tunneling layer disposed on the second pinned layer; and a second magnetic free layer disposed on the second tunneling layer, having a second free magnetization parallel to the easy axis. The top electrode connects the first free layer and the second free layer. The metal line route crosses the first MTJ device and the second MTJ device. The first free magnetization and the second free magnetization at an initial state are set to along the easy axis but mutually anti-parallel by a current flowing in the metal line route to generate magnetic fields parallel to the easy axis but opposite direction, respectively. The included angle between the pinned direction and the easy axis is substantially 45 or 135 degrees. A magnetic field sensing direction is perpendicular to the easy axis on the substrate.

In an embodiment of disclosure, a 2-axis in-plane magnetic field sensor comprises a substrate, a first in-plane magnetic field sensor and a second in-plane magnetic field sensor. The first in-plane magnetic field sensor has a first pinned direction and a first easy axis. The second in-plane magnetic field sensor has a second pinned direction and a second easy axis. The first easy axis is orthogonal to the second easy axis, and the first pinned direction and the second pinned direction both are parallel to a bisection direction, the bisection direction having angles of 45 degrees to the first easy axis and the second easy axis, respectively. The first in-plane magnetic field sensor comprises a first magnetic sensing structure of TMR and a first metal line route. The first magnetic sensing structure of TMR comprises a first bottom electrode on the substrate; a first MTJ device comprising a first pinned layer on the first bottom electrode, having a first pinned magnetization at the first pinned direction; a first tunneling layer, disposed on the first pinned layer; and a first magnetic free layer, disposed on the first tunneling layer, having a first free magnetization parallel to the first easy axis and a first included angle formed between the first pinned direction and the first easy axis; a second MTJ device comprising a second pinned layer on the first bottom electrode, having a second pinned magnetization at the first pinned direction; a second tunneling layer, disposed on the second pinned layer; and a second magnetic free layer, disposed on the second tunneling layer, having a second free magnetization parallel to the first easy axis; and a first top electrode connects the first free layer and the second free layer; and the first metal line route crosses the first MTJ device and the second MTJ device. The first free magnetization and the second free magnetization at an initial state are parallel to the first easy axis but mutual anti-parallel, by a current flowing in the first metal line route to generate magnetic fields parallel to the first easy axis but opposite direction, respectively. The first included angle between the first pinned direction and the first easy axis is substantially 45 or 135 degrees. A first magnetic field sensing direction is perpendicular to the first easy axis on the first substrate. The second in-plane magnetic field sensor comprises a second magnetic sensing structure of TMR and a second metal line route. The second magnetic sensing structure of TMR comprises a second bottom electrode on the substrate; a third MTJ device comprising a third pinned layer on the third bottom electrode, having a third pinned magnetization at the second pinned direction; a third tunneling layer, disposed on the third pinned layer; and a third magnetic free layer, disposed on the third tunneling layer, having a third free magnetization parallel to the second easy axis and a second included angle formed between the second pinned direction and the second easy axis; a fourth MTJ device comprising a fourth pinned layer on the second bottom electrode, having a fourth pinned magnetization at the second pinned direction; a fourth tunneling layer, disposed on the fourth pinned layer; and a fourth magnetic free layer, disposed on the fourth tunneling layer, having a fourth free magnetization parallel to the second easy axis. The second top electrode connects the third magnetic free layer and the fourth magnetic free layer; and the second metal line route crosses the third MTJ device and the fourth MTJ device. The third free magnetization and the fourth free magnetization at the initial state are parallel to the second easy axis but mutual anti-parallel, by a current flowing in the second metal line route to generate magnetic fields parallel to the second easy axis but opposite direction, respectively. The second included angle between the second pinned direction and the second easy axis is substantially 45 or 135 degrees, wherein a second magnetic field sensing direction is perpendicular to the second easy axis on the second substrate.

In an embodiment of disclosure, an out-of-plane magnetic field sensor disposed on a substrate having a magnetic field sensing direction perpendicular to the substrate comprises a groove or bulge structure, a first magnetic field sensing structure of TMR, a second magnetic field sensing structure of TMR, and a metal line route. The groove or bulge structure on the substrate has a first incline and a second incline. The first incline and the second incline have a same bevel to the substrate and are symmetrically flipped with respect to a medial axle of the groove or bulge structure. The first magnetic field sensing structure of TMR is formed on the first incline, having a first pinned direction and a first easy axis, comprising: a first bottom electrode on the first incline; a first MTJ device comprising a first pinned layer on the first bottom electrode, having a first pinned magnetization at the first pinned direction; a first tunneling layer, disposed on the first pinned layer; and a first magnetic free layer, disposed on the first tunneling layer, having a first free magnetization parallel to the first easy axis and a first included angle formed between the first pinned direction and the first easy axis; a second MTJ device comprising: a second pinned layer on the first bottom electrode, having a second pinned magnetization at the first pinned direction; a second tunneling layer, disposed on the second pinned layer; and a second magnetic free layer, disposed on the second tunneling layer, having a second free magnetization parallel to the first easy axis; and a first top electrode connecting the first magnetic free layer and the second magnetic free layer. The second magnetic field sensing structure of TMR is formed on the second incline, having a second pinned direction and a second easy axis, comprising: a second bottom electrode on the second incline; a third MTJ device comprising: a third pinned layer on the second bottom electrode, having a third pinned magnetization at the second pinned direction; a third tunneling layer disposed on the third pinned layer; and a third magnetic free layer disposed on the third tunneling layer, having a third free magnetization parallel to the second easy axis and a second included angle formed between the second pinned direction and the second easy axis; a fourth MTJ device comprising: a fourth pinned layer on the second bottom electrode, having a fourth pinned magnetization at the second pinned direction; a fourth tunneling layer, disposed on the fourth pinned layer; and a fourth magnetic free layer, disposed on the fourth tunneling layer, having a fourth free magnetization parallel to the second easy axis; and a second top electrode connecting the third magnetic free layer and the fourth magnetic free layer. The metal line route crosses the first MTJ device, the second MTJ device, the third MTJ device and the fourth MTJ device, and a current flowing in the metal line route can generate magnetic fields parallel to the first easy axis but opposite direction to set the first free magnetization and the second free magnetization at an initial state are parallel to the first easy axis but mutual anti-parallel, and magnetic fields parallel the second easy axis but opposite direction to set the third free magnetization and the fourth free magnetization at the initial state are parallel to the second easy axis but mutual anti-parallel. The first easy axis and the second easy axis are parallel to the medial axle of the groove or bulge structure. The first bottom electrode of the first magnetic field sensing structure of TMR connects with the second bottom electrode of the second magnetic field sensing structure of TMR. The first top electrode of the first magnetic field sensing structure of TMR connects with the second top electrode of the second magnetic field sensing structure of TMR.

In an embodiment of the disclosure, a 3-axis magnetic field sensor includes a substrate, a foregoing 2-axis in-plane magnetic field sensor, and a foregoing out-of-plane magnetic field sensor. The 2-axis magnetic field sensor comprises two in-plane magnetic sensors, wherein the medial axle of the out-of plane magnetic field sensor is parallel to the bisection direction of the two in-plane magnetic field sensors.

In an embodiment of the disclosure, a method for a 3-axis magnetic field sensor to set the pinned direction of each magnetic field sensing structure of TMR, simultaneously, is provided. By applying a slantwise field during annealing process, having a zenith angle to Z-axis perpendicular to the substrate and also its projection on the substrate has an azimuth angle of 45 degree to X- and Y-axis. The zenith angle is determined by setting tangent of zenith angle equals to sine of bevel angle.

According to the disclosure, a method for a 3-axis magnetic field sensor to set the pinned direction of each magnetic field sensing structure of TMR, simultaneously, is provided. By applying dual fields during annealing process, a horizontal field and a perpendicular field are applied simultaneously. The perpendicular field is parallel to the Z axis, the horizontal field has an azimuth angle of 45 degree to X- and Y-axis and a magnitude ratio to perpendicular filed equals to sine of bevel angle.

In an embodiment of disclosure, a sensing circuit to transfer the sensed magnetic field into electronic signal is provided. The circuit is comprised of a bias voltage unit, a clamped voltage current mirror unit, and a signal transfer amplifying unit. A same magnetic field sensor is used as zero-field reference, but its free magnetizations are locked by a current generated ampere field during magnetic field sensing. The bias voltage unit generates the clamp voltage to clamp voltage current mirror and bias a same voltage to the magnetic field sensor and zero-field reference. The clamp voltage current mirror unit brings the magnetic field free current of the zero-field reference to the magnetic field sensor. The current of the magnetic field sensor is a sum of zero-field reference current and sensed current due to conductivity changed by magnetic field. The sensed current is converted to sensed voltage by flowing through a resistor of signal transfer amplifying unit.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view, schematically illustrating a conventional TMR magnetic field sensor.

FIG. 1B is a top view of the conventional TMR magnetic field sensor in FIG. 1A.

FIGS. 2A-2B are drawings, schematically illustrating a Wheatstone bridge circuit without and with shielding.

FIGS. 3A-3B are drawings, schematically illustrating the cross-sectional view and the top view along the line at the easy-axis of a mutual supplement tunneling magneto-resistor, called MS-TMR, according to an embodiment of the disclosure.

FIGS. 4A-4B are drawings, schematically illustrating the calculation of normalized conductivity.

FIGS. 5A-5B are drawings, schematically illustrating micro-magnetism simulations of the MS-TMR for demonstrating that the conductivity has linearity with the applied magnetic field.

FIG. 6 is a drawing, schematically illustrating a 2-axis magnetic field sensor on a substrate, according to an embodiment of the disclosure.

FIGS. 7A-7C are top view and cross-sectional view, schematically illustrating a derivational Z-axis magnetic field sensor, under consideration in the disclosure.

FIGS. 8A-8B are drawings, schematically illustrating a geometric coordinate relation for the incline with respect to the substrate, according to an embodiment of disclosure.

FIG. 9 is a top view, schematically illustrating a Z-axis magnetic field sensor, according to an embodiment of the disclosure.

FIG. 10 is top view, schematically illustrating a 3-axis magnetic field sensor, according to an embodiment of disclosure.

FIG. 11 is a drawing, schematically illustrating a methods to set the pinned direction of each MS-TMR by applying a single slantwise field or dual fields during anneal process, according to an embodiment of disclosure.

FIG. 12 is a drawing, schematically illustrating circuits for transferring the sensed magnetic field into electronic signal of a magnetic field sensor, according to an embodiment of the disclosure.

### DESCRIPTION OF DISCLOSED EMBODIMENTS

In the disclosure, a structure of TMR to sense magnetic field and a configuration and method to form a 3-axis TMR magnetic field sensor on a substrate, simultaneously, has been proposed. Several embodiments are provided for descriptions, however, the disclosure is not just limited to the embodiment.

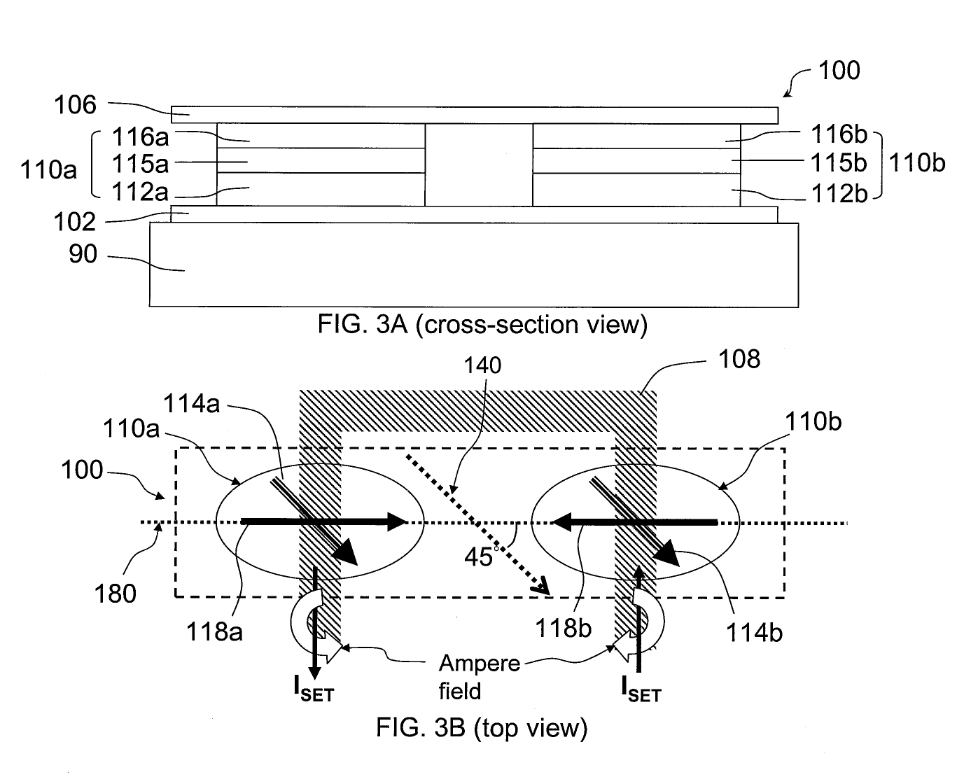

FIGS. 3A-3B are drawings, schematically illustrating the cross-sectional view and the top view along the line at the easy-axis of a mutual supplement tunneling magneto-resistor, called MS-TMR, according to an embodiment of the disclosure. In FIGS. 3A-3B, the MS-TMR 100 includes a bottom electrode 102 of conducting material, such as Ta, Ti, TiN, TaN, Al, Cu, Ru, . . . etc., on a substrate 90 and a top electrode 106 of conducting material, such as Ta, Ti, TiN, TaN, Al, Cu, Ru, . . . etc., and a first and a second MTJ (Magnetic Tunneling Junction) devices 110a, 110b, disposed between the bottom electrode 102 and the top electrode 106. The first and second MTJ devices 110a, 110b have a collinear easy-axis 180. The first MTJ device 110a includes a pinned layer 112a of magnetic material, such as NiFe, CoFe, CoFeB, . . . etc., formed on the bottom electrode 102 and has a first pinned magnetization 114a parallel to a pinned direction 140 which has an angle of 45 degrees to the easy-axis 180. A first tunneling layer 115a of non-magnetic material, such as AlO, MgO, . . . etc., is formed on the first pinned layer 112a. A first free layer 116a of magnetic material, such as NiFe, CoFe, CoFeB, . . . etc., is formed on the first tunneling layer 115a and has a first free magnetization 118a initially parallel to the easy-axis 180. The top electrode 106 connects the first free layer 116a.

The second MTJ device 110b has the same structure pattern and film stack as the first MTJ devices 110a. The second MTJ device 110b includes a second pinned layer 112b of magnetic material formed on the bottom electrode 102 and has a second pinned magnetization 114b also parallel to the same pinned direction 140. A second tunneling layer 115b of non-magnetic material is formed on the second pinned layer 112b. A second free layer 116b of magnetic material is formed on the second tunneling layer 115b and has a second free magnetization 118b initially parallel to the easy-axis 180 but anti-parallel to the first free magnetization 118a. The top electrode 106 connects the second free layer 116b.

A metal line route 108 passes across the first and the second MTJ devices 110a, 110b and a set current I_{SET} can be applied to generate ampere fields thereon. The ampere fields applying on the first and second MTJ devices 110a, 110b both are parallel to the easy-axis 180 but directionally opposite, thus the first and second free magnetizations 118a, 118b are set to be anti-parallel.

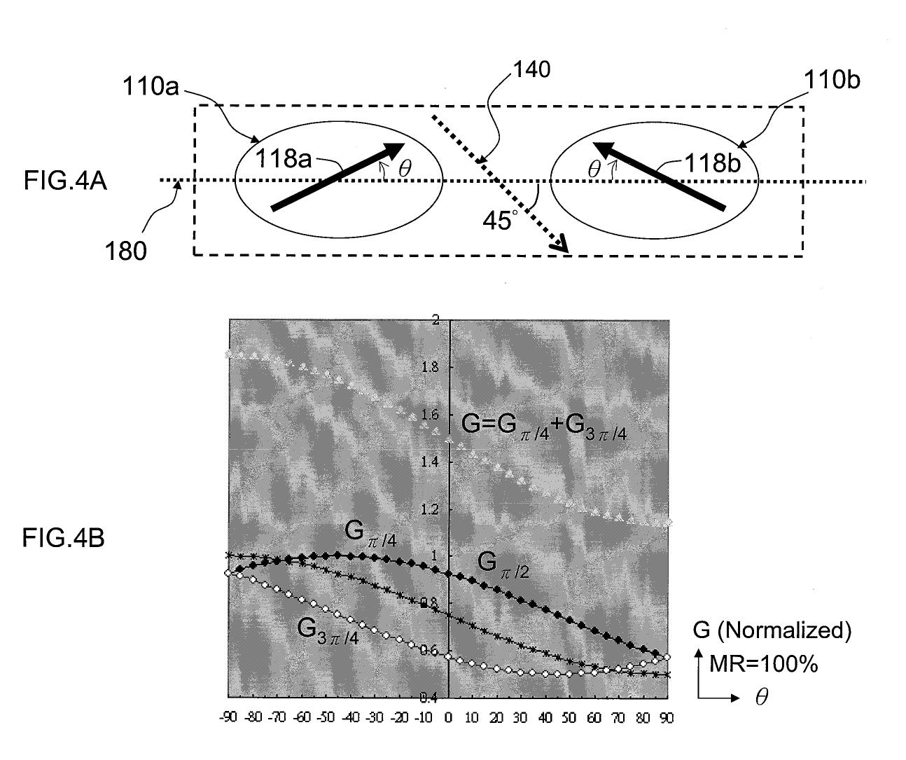

According to the above disclosures, the conductivity of the MS-TMR 100 can be obtained from Eq. (1). The normalized conductivity is calculated and shown in FIGS. 4A-4B, where the conductivity of a typical TMR also shown for reference.

$$\begin{matrix}\begin{matrix}G = {G}_{π / 4} + {G}_{3 π / 4} \\ = {G}_{P} [ 1 + \frac{1 - \frac{MR}{\sqrt{2}} \times sin θ}{1 + MR} ] , where\end{matrix} & ( 1 ) \\ \begin{matrix}{G}_{π / 4} = \frac{{G}_{P}}{2} [ 1 + \frac{1 + MR cos ( \frac{π}{4} + θ )}{1 + MR} ] \\ = \frac{{G}_{P}}{2} [ 1 + \frac{1 + \frac{MR}{\sqrt{2}} ( cos θ - sin θ}{1 + MR} ] , and\end{matrix} & ( 2 ) \\ \begin{matrix}{G}_{3 π / 4} = \frac{{G}_{P}}{2} [ 1 + \frac{1 + MRcos ( \frac{3 π}{4} + θ )}{1 + MR} ] \\ = \frac{{G}_{P}}{2} [ 1 + \frac{1 + \frac{MR}{\sqrt{2}} ( - cos θ - sin θ )}{1 + MR} ] .\end{matrix} & ( 3 )\end{matrix}$$

The Eq. (2) and Eq. (3) are the conductivity of the first and second MTJ device 110a, 110b, respectively. The first and second MTJ devices 110a, 110b supposedly have same parameters in which MR is the magneto-resistance ratio, G_{P} is the conductivity as free layer magnetization is parallel to the pinned layer magnetization, and θ is the angle between free magnetization and easy-axis as applied magnetic field H_{⊥}is perpendicular to the easy-axis. Assuming the applied magnetic field is smaller than the coercivity H_{C} of MTJ device, then

$$sin θ ≅ \frac{{H}_{⊥}}{{H}_{C}}$$

and the magnetic field can be sensed linearly as Eq. (4) described.

$$G = {G}_{P} [ 1 + \frac{1 - \frac{MR}{\sqrt{2}} \frac{{H}_{⊥}}{{H}_{C}}}{1 + MR} ] . \qquad ( 4 )$$

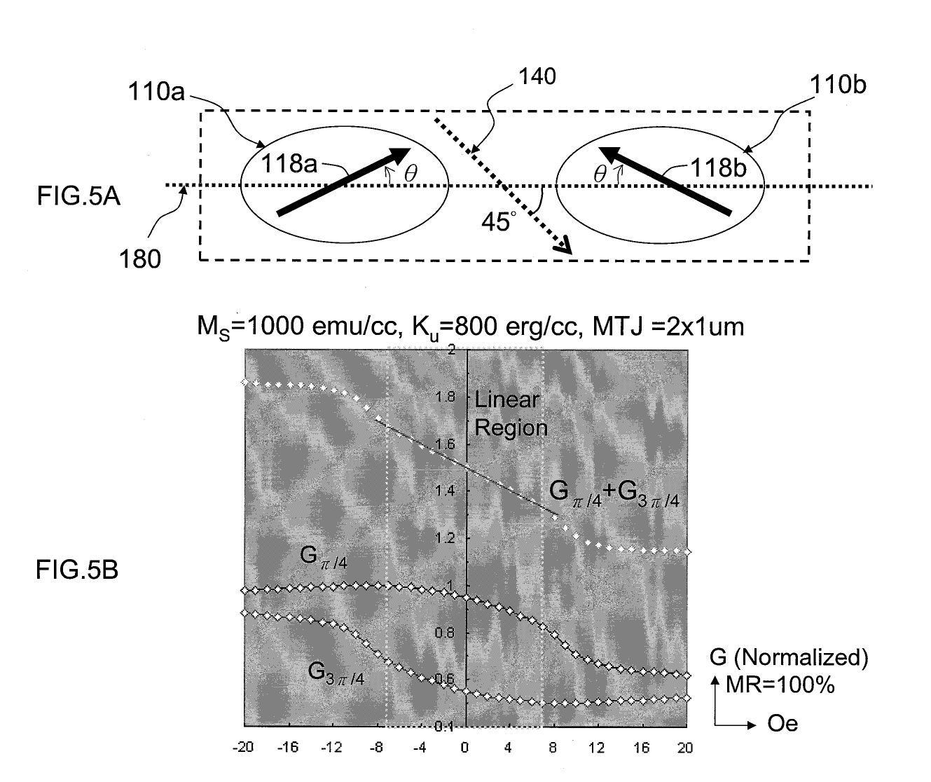

In FIGS. 5A-5B, a further micro-magnetism simulations of the MS-TMR 100 demonstrates that the conductivity has a linearity with the applied magnetic field, where the first and second MTJ devices 110a, 110b have the same oval shape with major length of 2 microns and minor length of 1 micron, the same thickness 10 Å of free layers, the saturation magnetization Ms=1000 emu/cc of the free and pinned layers, and the anisotropy constant Ku=800 erg/cc of the pinned layer. In this example, the conductivity of the MS-TMR 100 is linearly decreased as applied magnetic field increased. As the pinned direction is reversed, then a linearly increasing of conductivity can be obtained.

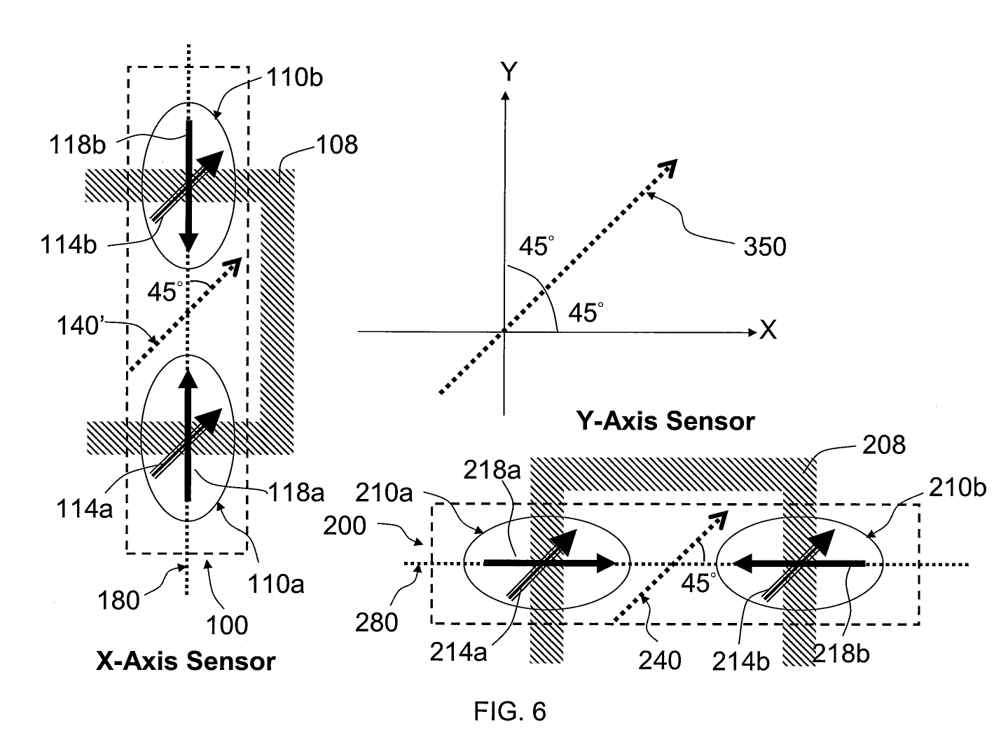

FIG. 6 is a drawing, schematically illustrating a 2-axis magnetic field sensor on a substrate, according to an embodiment of the disclosure. In following embodiment for the 2-axis magnetic field sensor, the devices, such as the multiple MS-TMR and so on, are indicated with a restarted element sequence for easy description. An X-axis magnetic field sensor comprises a first MS-TMR 100 having a first easy-axis 180 parallel to the Y-axis and a first pinned direction 140, and a first metal line route 108. A Y-axis magnetic field sensor comprises a second MS-TMR 200 having a second easy-axis 280 parallel to the X-axis and a second pinned direction 240, and a second metal line route 208. The first and second pinned directions 140, 240 both are parallel to a bisection direction 350 of the coordinate system with an angle of 45 degrees to X-axis and Y-axis on the substrate. The first MS-TMR 100 is the same structure and numbers as recited in FIGS. 3A-3B for easy description in all example of the disclosure, and not repeated as follow. The first MS-TMR 100 includes a first MTJ device 110a having a first pinned magnetization 114a and a first free magnetization 118a; a second MTJ device 110b having a second pinned magnetization 114b and a second free magnetization 118b. All of the first and second pinned magnetizations 114a, 114b are parallel to the first pinned direction 140. The first and second free magnetizations 118a, 118b initially are parallel to the first easy-axis 180 but mutual anti-parallel. The second MS-TMR 200 is the same structure as recited in FIGS. 3A-3B and includes a third MTJ device 210a having a third pinned magnetization 214a and a third free magnetization 218a; a fourth MTJ device 210b having a fourth pinned magnetization 214b and a fourth free magnetizations 218b. The third and fourth pinned magnetizations 214a, 214b are parallel to the second pinned direction 240. The third and fourth free magnetizations 218a, 218b initially are parallel to the second easy-axis 280 but mutually anti-parallel.

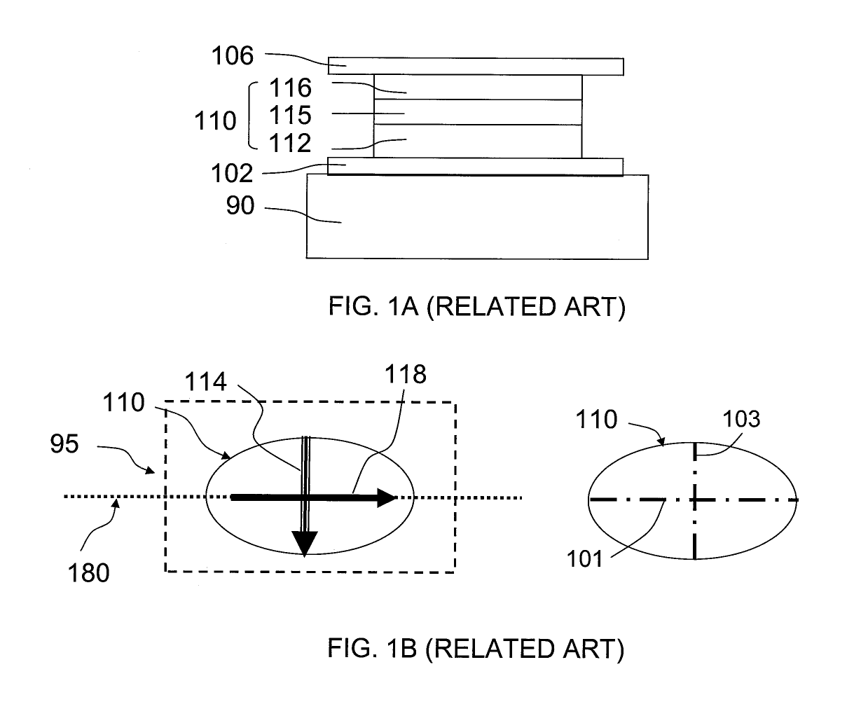

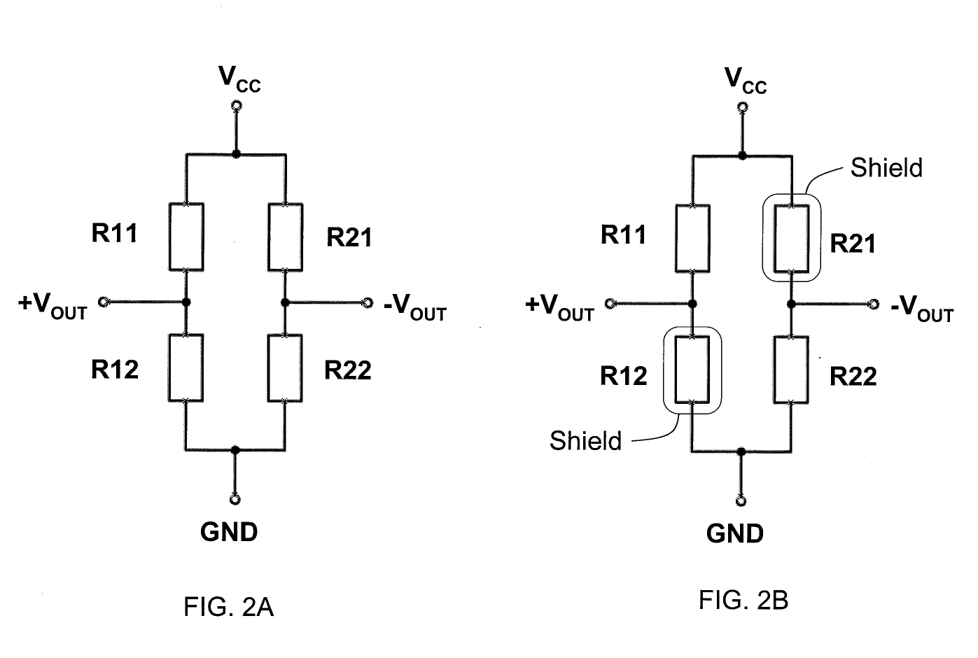

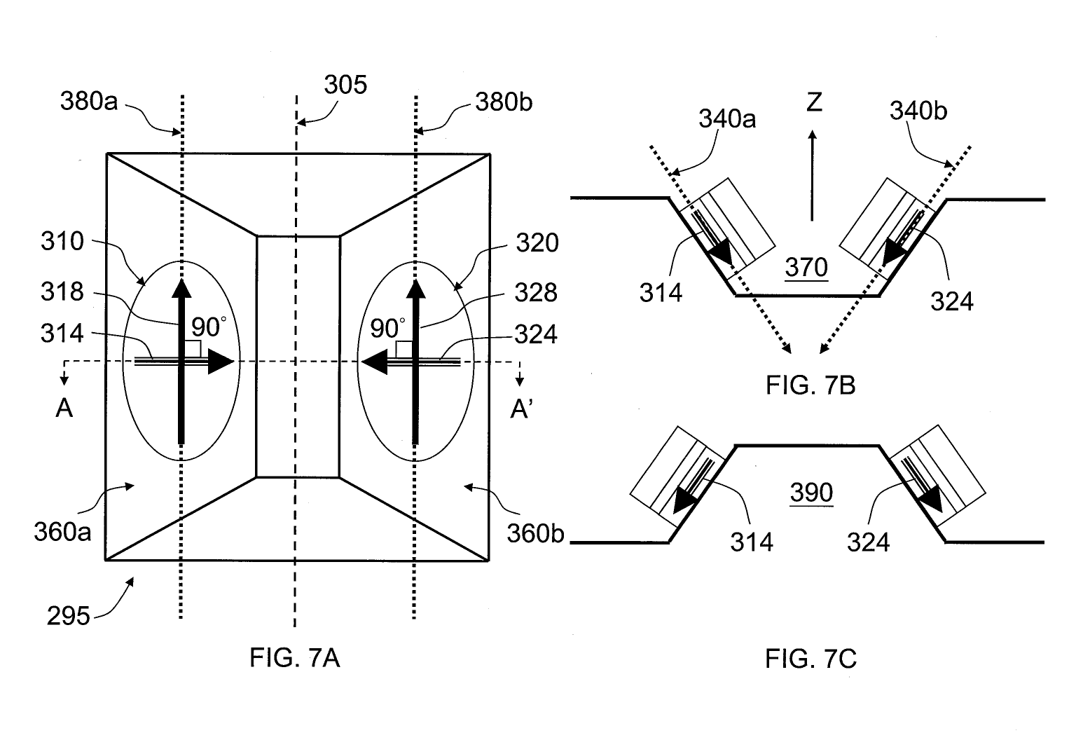

In FIGS. 7A-7C, a theoretical derivation for the Z-axis magnetic field sensor in consideration is described and the top view and cross section view along A-A′. The Z-axis magnetic field sensor 295 is a parallel connection of a first TMR 310 formed on the first incline 360a and a second TMR 320 formed on the second incline 360b. The first TMR 310 and the second TMR 320 are the same structures as recited in FIGS. 1A-1B. The first and second inclines 360a, 360b have same bevels to the substrate and are symmetrically flipped with respect to the medial axle 305 of a groove 370 structure or a bulge 390 structure on a substrate. The first and second TMRs 310, 320 have same pattern and same film stacks. The first TMR 310 has a first free magnetization 318 initially parallel to the first easy-axis 380a, and a first pinned magnetization 314 parallel to the first pinned direction 340a. The first easy-axis 380a is parallel to a medial axle 305 on the substrate and the first pinned direction 340a is perpendicular to the first easy-axis 380a on the first incline 360a. The second TMR 320 has a second free magnetization 328 initially parallel to the second easy-axis 380b, and a second pinned magnetization 324 parallel to the second pinned direction 340b. The second easy-axis 380b also is parallel to a medial axle 305 on the substrate and the second pinned direction 340b is perpendicular to the second easy-axis 380b on the second incline 360b. The first and second pinned directions 340a, 340b both are either upward or downward. Because each TMR has its pinned direction perpendicular to its easy-axis, hence the first and second free magnetizations 318, 328 can initially be either parallel or anti-parallel. The first TMR 310 has a magnetic field sensing direction parallel to the perpendicular line of the first easy-axis 380a on the first incline 360a. Likewise, the second TMR 320 has a magnetic field sensing direction parallel to the perpendicular line of the second easy-axis 380b on the second incline 360b. The first and second pinned directions 314, 324 can be set by applying a field perpendicular to the substrate during anneal process.

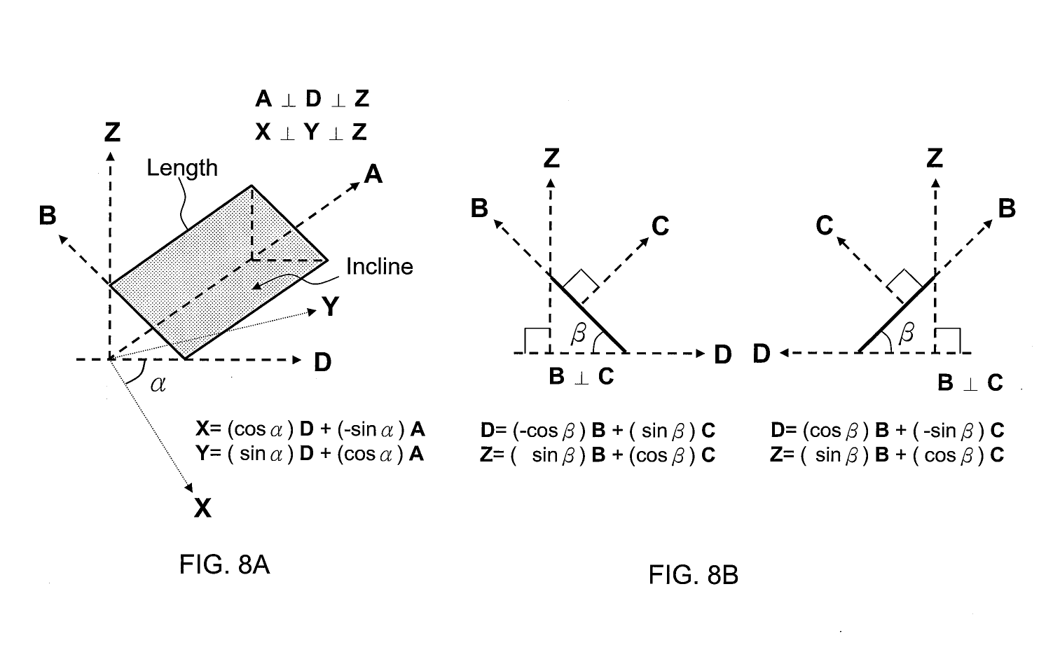

Before investigating the physical phenomena in the structure of FIG. 7A, a coordinate system transformation for the two inclines is considered. FIGS. 8A-8B are drawings, schematically illustrating a geometric coordinate relation for the incline with respect to the substrate, according to an embodiment of disclosure. In FIGS. 8A-8B, the coordinate transformation on the inclines is further consideration. For an incline on a substrate as shown in FIGS. 8A-8B, one can define: a direction A on the substrate is parallel to the lengthwise direction; a direction D on the substrate is perpendicular to the direction A on the substrate and has an azimuth angle α to X-axis; a direction Z is perpendicular to the substrate and parallel to the Z-axis. Furthermore, from the cross sectional view as shown in FIG. 8B, a direction B can be defined to be parallel to the incline with a bevel angle β to the direction D. A direction C is normal to the incline. Therefore, a magnetic filed can be represented by the fields with directions parallel to the direction A, direction B and direction C of an incline, respectively.

According to the above descriptions, as a magnetic field is applied to the first (Left side) and second (Right side) TMRs 310, 320, then their conductivities can be expressed as Eq. (5) and Eq. (6), respectively.

$$\begin{matrix}{G}_{L} = \frac{{G}_{P}}{2} [ 1 + \frac{1 + \frac{MR}{{H}_{C}} ( {H}_{X} cos α cos β + {H}_{Y} sin α cos β - {H}_{z} sin β )}{1 + MR} ] and & ( 5 ) \\ {G}_{R} = \frac{{G}_{P}}{2} [ 1 + \frac{1 - \frac{MR}{{H}_{C}} ( {H}_{X} cos α cos β + {H}_{Y} sin α cos β + {H}_{z} sin β )}{1 + MR} ] . & ( 6 )\end{matrix}$$

As connecting them in parallel, the sensed signals of X-axis and Y-axis magnetic field are mutually canceled and the sensed signal of Z-axis magnetic field remained, written as Eq. (7).

$$\begin{matrix}G = {G}_{L} + {G}_{R} \\ = {G}_{P} ( 1 + \frac{1 - MR \frac{{H}_{Z}}{{H}_{C}} sin β}{1 + MR} ) .\end{matrix} \qquad ( 7 )$$

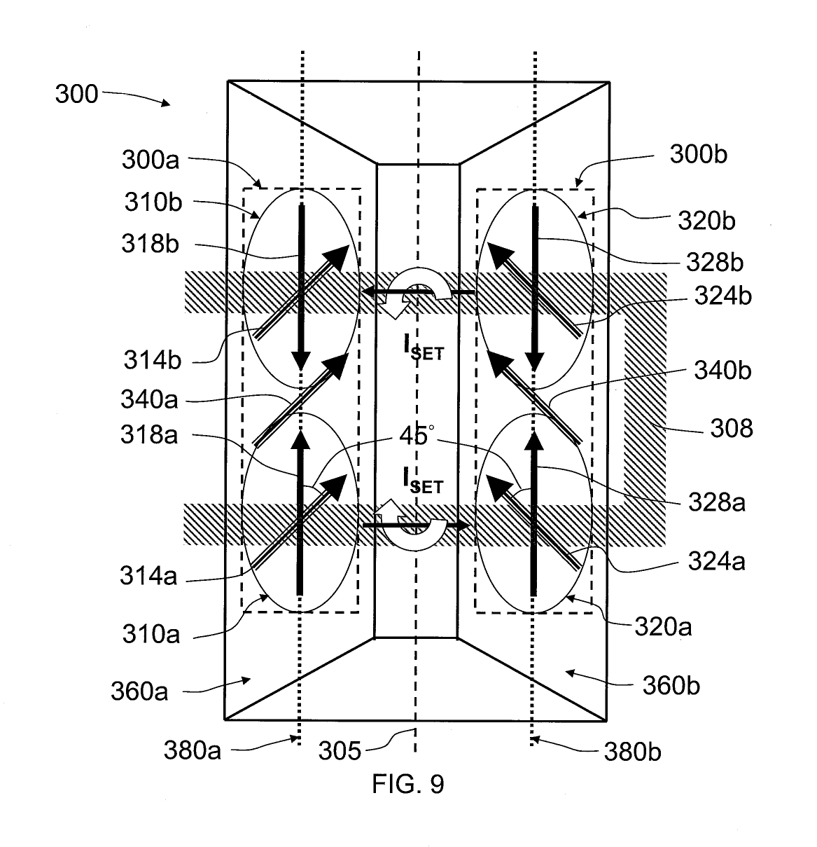

In fact, the Z-axis magnetic field sensor 300 as described in FIGS. 7A-7B, these two TMRs can be replaced by two MS-TMRs. FIG. 9 is a top view, schematically illustrating a Z-axis magnetic field sensor, according to an embodiment of the disclosure. In FIG. 9, an embodiment of a Z-axis magnetic field sensor 300 is disclosed, according to the foregoing descriptions, two same MS-TMRs are substituted for the two TMRs on the first and second inclines. The first and second inclines 360a, 360b disposed on a groove or bulge. In following embodiment for the Z-axis magnetic field sensor, the devices, such as the multiple MS-TMRs with the MTJ devices and so on, are indicated with a restarted element sequence for easy description. A first MS-TMR 300a has a first pinned direction 340a with an angle of 45 degree to a first easy-axis 380a on the first incline 360a, a second MS-TMR 300b has a second pinned direction 340b with an angle of 45 degrees to a second easy-axis 380b on the second incline 360b.

The first MS-TMR 300a includes a first MTJ device 310a and a second MTJ device 310b on the first incline 360a. The first MTJ device 310a has a first free magnetization 318a and a first pinned magnetization 314a; the second MTJ device 310b has a second free magnetization 318b and a second pinned magnetization 314b. The first and second pinned magnetizations 314a, 314b both are parallel to the first pinned direction 340a, the first and second free magnetizations 318a, 318b both initially are parallel to the first easy-axis 380a but set to be mutually anti-parallel by the generated ampere fields of a current flowing in the metal line route 308. The first MTJ device 310a and the second MTJ device 310b are sandwiched between a top electrode and a bottom electrode, and having the same structures as recited in FIGS. 3A-3B.

The second MS-TMR 300b includes a third MTJ device 320a and a fourth MTJ device 320b on the second incline 360b. The third MTJ device 320a has a third free magnetization 328a and a third pinned magnetization 324a. The fourth MTJ device 320b has a fourth free magnetization 328b and a fourth magnetization 324b. Likewise, the third MTJ device 320a and the fourth MTJ device 320b are sandwiched between a top electrode and a bottom electrode. In the first and second MS-TMRs 300a and 300b, both the top electrodes are connected together and both the bottom electrodes are connected together. The third and fourth pinned magnetizations 324a, 324b both are parallel to the second pinned direction 340b, the third and fourth free magnetizations 328a, 328b both initially are parallel to the second easy-axis 380b but set to be mutually anti-parallel by the generated ampere fields of a current flowing in the metal line route 308. The third MTJ device 320a and the fourth MTJ device 320b are sandwiched between a top electrode and a bottom electrode, and having the same structures as recited in FIGS. 3A-3B.

The first easy-axis and the second easy-axis 380a, 380b are parallel to a medial axle 305 on the substrate. The first and second pinned directions 340a, 340b are symmetrically flipped on the substrate, and have an angle of 45 degree to their easy axes on their own inclines, respectively. The conductivity of the Z-axis magnetic field sensor 300 is written as Eq (8).

$$G = 2 {G}_{P} ( 1 + \frac{1 - \frac{MR}{\sqrt{2}} \frac{{H}_{Z}}{{H}_{C}} sin β}{1 + MR} ) . \qquad ( 8 )$$

An additional potential is the bevel angle β of the inclines as shown in Eq. (8), because the parallel connection doubles the conductivity, hence the bevel angle β of the incline can be reduced.

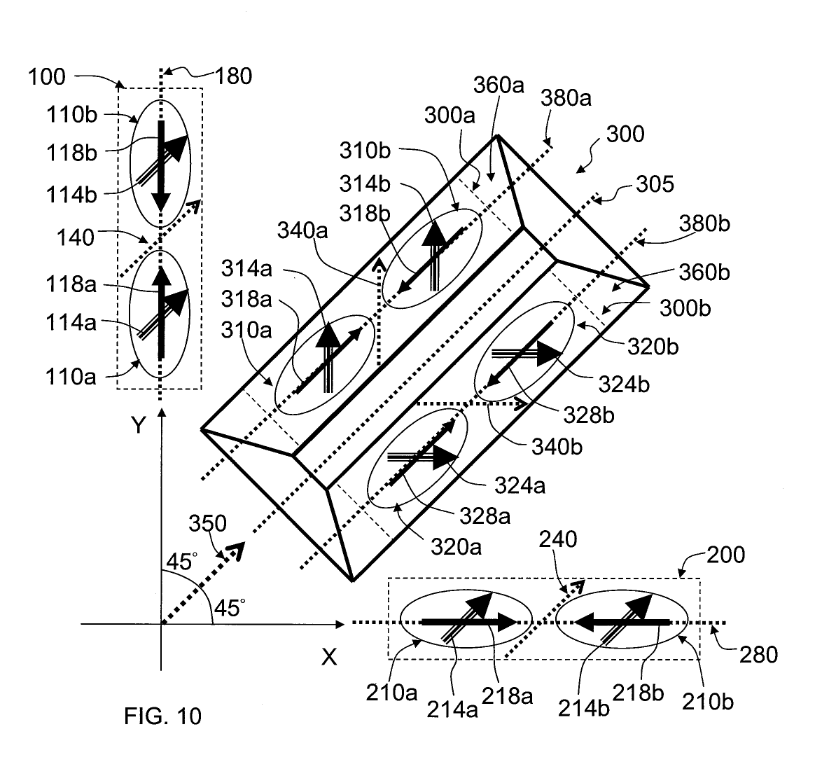

FIG. 10 is top view, schematically illustrating a 3-axis magnetic field sensor, according to an embodiment of disclosure. In FIG. 10, a 3-axis magnetic field sensor includes a 2-axis in-plane magnetic field sensor and a Z-axis out-of-plane magnetic field sensor, wherein the metal line routes of magnetic field sensor for generating magnetic field to set free magnetisms at initial states are not shown for easy description. For easy understanding, the detailed structures description of the first and second MS-TMR 100, 200 can be used the original numbers, and the detailed structures of the third and fourth MS-TMR 300a, 300b reedited the numbers as recited in FIG. 10. The first MS-TMR 100 and the second MS-TMR 200 includes the metal line route to cross two TMRs, respectively, as recited in FIG. 6, and not repeated the details again in following example. The 2-axis in-plane magnetic field sensor includes an X-axis magnetic field sensor is a first MS-TMR 100, having a first easy-axis 180 parallel to the Y-axis and a first pinned direction 140 parallel to bisection direction 350; a Y-axis magnetic field sensor is a second MS-TMR 200, having a second easy-axis 280 parallel to the X-axis and a second pinned direction 240 also parallel to the same bisection direction 350. The Z-axis magnetic field sensor 300 is a parallel connection of two MS-TMRs on the symmetrically parallel inclines of a groove or a bulge, on which a third MS-TMR 300a and a fourth MS-TMR 300b are disposed on the first and second inclines 360a, 360b. The third MS-TMR 300a has a third easy-axis 380a and a third pinned direction 340a, and the fourth MS-TMR 300b has an fourth easy-axis 380b and a fourth pinned direction 340b. The third easy-axis 380a and the fourth easy-axis 380b are parallel to the same medial axle 305 on the substrate. The medial axle 305 is parallel to the bisection direction 350 which has an angle of 45 degrees to the X- and Y-axis. The third and fourth pinned directions 340a, 340b have an angle of 45 degrees to the third and fourth easy-axis 380a, 380b, respectively. The Z-axis magnetic field sensor 300 includes the metal line route to cross the third MS-TMR 300a and the fourth MS-TMR 300b as recited in FIG. 9, and not repeated the details again in following example.

The first MS-TMR 100 has a first MTJ device 110a with a first free magnetization 118a and a first pinned magnetization 114a, a second MTJ device 110b with a second free magnetization 118b and a second pinned magnetization 114b. The first and second pinned magnetizations 114a, 114b are parallel to a first pinned direction 140. The first and second free magnetizations 118a, 118b initially are parallel to the first easy-axis 180 but set in mutual anti-parallel. The second MS-TMR 200 has a third MTJ device 210a with a third free magnetization 218a and a third pinned magnetization 214a; a fourth MTJ device 210b with a fourth free magnetization 218b and a fourth pinned magnetization 214b. The third and fourth pinned magnetizations 214a, 214b are parallel to a second pinned direction 240. The third and fourth free magnetizations 218a, 218b initially are parallel to the second easy-axis 280 but set in mutual anti-parallel. The third MS-TMR 300a has a fifth MTJ device 310a with a fifth free magnetization 318a and a fifth pinned magnetization 314a; a sixth MTJ device 310b with a sixth free magnetization 318b and a sixth pinned magnetization 314b. The fifth and sixth pinned magnetizations 314a, 314b both are parallel to the third pinned direction 340a. The fifth and sixth free magnetizations 318a, 318b initially are parallel to the third easy-axis 380a but set in mutual anti-parallel. The fourth MS-TMR 300b has a seventh MTJ device 320a with a seventh free magnetization 328a and a seventh pinned magnetization 324a; a eighth MTJ device 320b with a eighth free magnetization 328b and a eighth pinned magnetization 324b. The seventh and eighth pinned magnetizations 324a, 324b both are parallel to the fourth pinned direction 340b. The seventh and eighth free magnetizations 328a, 328b initially are parallel to the fourth easy-axis 380b but set in mutual anti-parallel.

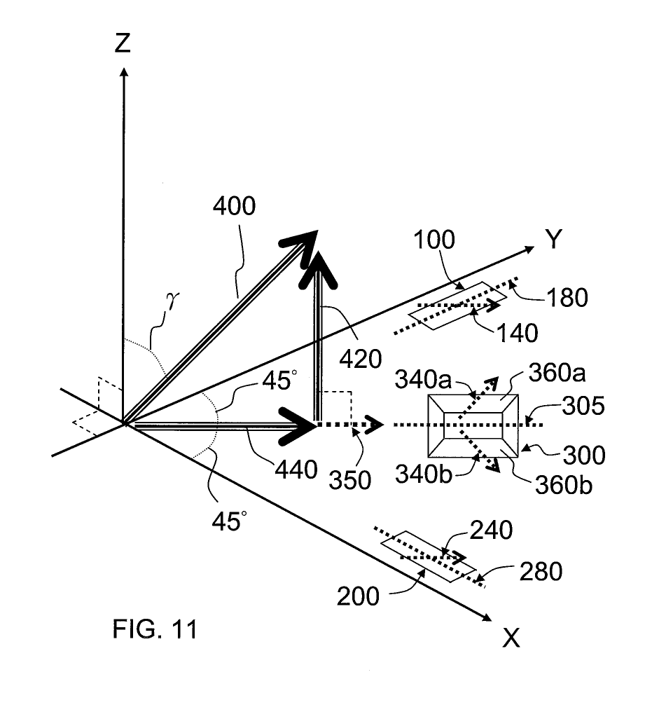

FIG. 11 is a drawing, schematically illustrating a methods to set the pinned direction of each MS-TMR by applying a single slantwise field or dual fields during anneal process, according to an embodiment of disclosure. For easy understanding, the detailed structures description of the first and second MS-TMR 100, 200 can be used the original numbers, and the detailed structures of the third and fourth MS-TMR 300a, 300b can be used the original numbers as recited in FIG. 10. A method, called slantwise field anneal, to set the pinned direction of each MS-TMR by applying a single field during anneal process is provided. The layout of a 3-axis magnetic field sensor includes an X-axis magnetic field sensor has a first easy-axis 180 parallel to the Y-axis and a first pinned direction 140. Further, a Y-axis magnetic field sensor 200 has a second easy-axis 280 parallel to the X-Axis and a second pinned direction 240. A Z-axis magnetic field sensor 300 has a medial axle 305 parallel to a bisection direction 350 and a third and a fourth pinned directions 340a, 340b. A slantwise field 400, having an zenith angle γ to Z-axis perpendicular to the substrate and an azimuth angle of 45 degrees to the X-axis, is applied during anneal process. Therefore, the projection of the slantwise field on the substrate is parallel to the bisection direction 350 and has angle 45 degrees to X- and Y- axis. Then, the first and second pinned directions 140, 240 are set to be parallel to the bisection direction 350. The zenith angle γ is set according to bevel angle β of the incline and written as Eq. (9)

γ=tan⁻¹(sin β). (9)

Therefore, the projections of the slantwise field on the first and the second inclines 360a, 360b are symmetrically flipped and will have angles 45 degrees to the third and fourth easy-axis 380a, 380b. As a result, the third and the fourth pinned directions 340a, 340b are set to be parallel the projections of the slantwise field on the inclines 360a, 360b, respectively. For example, as the bevel angle β=54°, then the zenith and azimuth are γ=39° and α=45° for the slantwise field.

In real case, the typical anneal instrument be equipped a heavy and fixed on either horizontal or perpendicular orientation of single magnetic field generator, thus the azimuth and zenith is set by a handling instrument to rotate and tilt the substrate. The mechanical operation for tilting a substrate is complex and limits the precision, thus the yield tends to be impacted. Another method, called dual field anneal, is provided to improve the accuracy of the slantwise field direction and also shown the embodiment in FIG. 11, the slantwise field can be a composition of a zenith field 420, H_{Z} and an azimuth field 440, H_{AZ}. The zenith field 420 is parallel to the Z-axis, the azimuth field 440 is parallel the bisection direction 350, and the relationship is written as Eq. (10).

H_{AZ}=H_{Z} sin β, (10)

The mechanical operation of substrate titling can be replaced by electronic signal controlling of the horizontal and perpendicular orientations of magnetic field generators. Practically, an anneal instrument can be equipped a horizontal and a perpendicular orientations of magnetic field generators, easily and feasibly. Therefore, the pinned direction of each MS-TMR can be set by applying a horizontal azimuth field 440, H_{AZ} and a perpendicular zenith field 420, H_{Z}, simultaneously, during the anneal process.

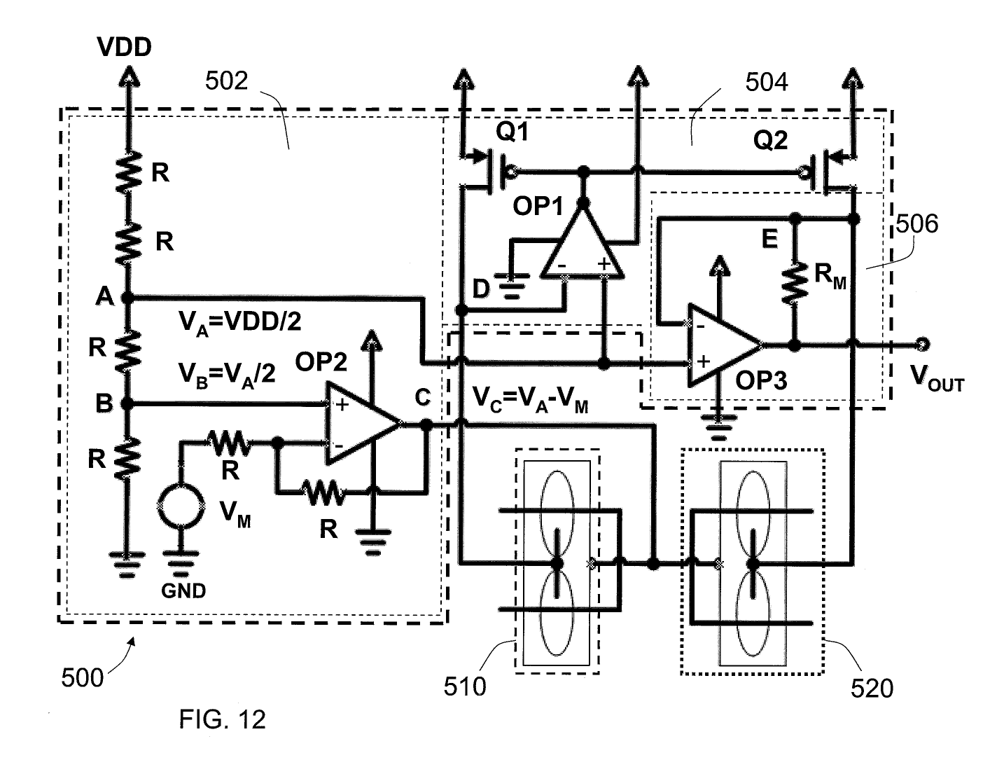

Based on the embodiments of foregoing disclosures, the back-end fabrication process of the magnetic field sensor as foregoing described can be integrated with the front-end process fabrication of the CMOS sensing circuit. FIG. 12 is a drawing, schematically illustrating circuits for transferring the sensed magnetic field into electronic signal of a magnetic field sensor, according to an embodiment of the disclosure. In contrast to the traditional Wheatstone bridge method, another one same sensor is used to be a zero-field reference and no shielding is necessary. During sensing magnetic field, a current is flowed in the metal route of the sensor as reference to generate ampere fields to freeze or lock the free magnetizations at initial state of paralleling easy-axis but mutual anti-parallel and the sensor acts as zero-field or magnetic field free.

In FIG. 12, the sensing circuit 500 includes three parts of bias voltage unit 502, the clamp voltage current mirror unit 504 and the signal transfer amplifying unit 506. An X-axis magnetic field sensor is an example, the bottom electrodes of the zero-field reference 510 and the magnetic field sensor 520 are connected to node C. The top electrode of the zero-field reference is connected to the node D and the top electrode of the magnetic field sensor 520 is connected to the node E. As can be understood, the zero-field reference 510 and the magnetic field sensor 520 in this example is for sensing x-directional of magnetic field. However, the circuit also available for sensing y-directional and the z-directional of magnetic field, by replacing the zero-reference 510 and the magnetic field sensor 520 with the Y-axis magnetic field sensor 200 or the Z-axis magnetic field sensor 300.

The bias voltage unit 502 includes a voltage dividing branch, a voltage subtraction circuit and a voltage source V_{M}. The voltage dividing branch is a series connection of four same resistors R between VDD and GND, so that the voltages of node A and node B are V_{A}=VDD/2 and V_{B}=V_{A}/2=VDD/4, respectively. The voltage source V_{M} supplies a fixed voltage to the zero-field reference and X-axis magnetic field sensor, i.e. bias voltage across the MTJ devices. The subtraction circuit includes a second operation amplifier Q2 having a positive input coupled to node B, a resistor R is connected between the OP2 negative input and OP2 output, a resistor R is connected between the OP2 negative input and voltage source V_{M}, and the OP2 output voltage of node C is V_{C}=V_{A}−V_{M}.

The clamp voltage current mirror unit 504 includes a current mirror and a voltage damper. The current mirror includes a first PMOS Q1 and second PMOS Q2, the source of Q1 and Q2 are the same and connected to VDD. The drain of Q1 joins to node D, the drain of Q2 joins to node E, the gate of Q1 connects to the gate of Q2. The voltage damper is a first operational amplifier OP1 having a positive input joined to node A, a negative input joined to nodes D. The OP1 output is joined to the gates of Q1 and Q2. The signal transfer amplifying unit 506 includes a third operational amplifier OP3 having a negative input joined to node E, a positive input joined to node A, and a resistor R_{M} connected between node E and OP3 output.

The power of the operational amplifiers OP1, OP2 and OP3 are a single VDD. Since the OP1 output is feedback to OP1 negative input via PMOS Q1 and the OP3 also has an output feedback to OP1 negative input via resistor R_{M}, hence the input differences of OP1 and OP2 are virtual ground and the voltages of nodes D and E are respectively clamped at the voltage V_{A}=VDD/2 of node A. The output of the signal transfer amplifying unit 506 is a half value of VDD as magnetic field free. This design can obtain the full range of signal amplification and favorable for ADC (Analog to Digital Convert). Since the voltages of nodes D and E are clamped and the OP1 output voltage is same for Q1 and Q2, hence drain current of Q2 is exactly same as the drain current of Q1. The bias voltage of MTJ devices of the magnetic field sensor and the zero-field reference all are fixed at the voltage V_{D}−V_{C}=V_{A}−(V_{A}−V_{M})=V_{M}. The drain current of Q1 is the current of zero-field reference 510. The current flowing through the magnetic field sensor 520 is a sum of currents of the zero-field reference and the sensed current due to the conductivity changed by magnetic field. Since the drain current of Q2 is a mirror of drain current of Q1 as magnetic field free, the sensed current flows from or into the operational amplifier OP3 output via the resistor R_{M}. The voltage of OP3 output Vout becomes the summation of the half value of VDD and the product of sensed current multiplied by the resistor R_{M}. As also previously mentioned, the sensing circuit is not just limited to the example of X-axis magnetic field sensor. The circuit can be used to the other axis at i.e. Y-axis or Z- axis with the corresponding magnetic field sensor, respectively.

The front-end CMOS process of sensing circuit can be integrated with the back-end process of the magnetic field sensors as an integrated circuit at the same substrate. However, the application circuit may also be separately fabricated, and the application circuit is not just limited to the proposed circuit. It should be also noted that the bottom electrode and the top electrode in each MS-TMR for connecting the pair of MTJ devices are not limited to the embodiments to sandwich the MTJ devices and can be other proper manner for implementation.

The disclosure proposes a structure of TMR (Tunneling Magneto-Resistor) to sense magnetic field and fabrication method to form a 3-axis TMR magnetic field sensor on a substrate, simultaneously, greatly reducing the complexity, cost of manufacture and also improve the sensitivity and accuracy.

It will be apparent to those skilled in the art that various modifications and variations can be made to the structure of the invention without departing from the scope or spirit of the invention. In view of the foregoing descriptions, it is intended that the invention covers modifications and variations of this invention if they fall within the scope of the following claims and their equivalents.

What is claimed is:

1. A magnetic field sensing structure of tunneling magneto-resistor (TMR), comprising:
a bottom electrode;
a first magnetic tunneling junction (MTJ) device, comprising:
a first pinned layer on the bottom electrode, having a first pinned magnetization at a pinned direction;
a first tunneling layer, disposed on the first pinned layer; and
a first magnetic free layer, disposed on the first tunneling layer, having a first free magnetization parallel to an easy axis and an included angle formed between the pinned direction and the easy axis;
a second MTJ device with an identical structure to the first MTJ device, comprising:
a second pinned layer on the bottom electrode, having a second pinned magnetization at the pinned direction;
a second tunneling layer, disposed on the second pinned layer; and
a second magnetic free layer, disposed on the second tunneling layer, having a second free magnetization parallel to the easy axis; and
a top electrode, connecting the first magnetic free layer and the second magnetic free layer,
wherein the first free magnetization and the second free magnetization at an initial state are parallel to the easy axis but mutual anti-parallel, and the included angle between the pinned direction and the easy axis is substantially 45 or 135 degrees.

2. An in-plane magnetic field sensor, comprising:
a substrate; and
a magnetic sensing structure of tunneling magneto-resistor (TMR) on the substrate,
wherein the magnetic sensing structure of TMR comprises:
a bottom electrode;
a first magnetic tunneling junction (MTJ) device, comprising:
a first pinned layer on the bottom electrode, having a first pinned magnetization at a pinned direction;
a first tunneling layer, disposed on the first pinned layer; and
a first magnetic free layer, disposed on the first tunneling layer, having a first free magnetization parallel to an easy axis and an included angle formed between the pinned direction and the easy axis;
a second MTJ device with an identical structure to the first MTJ device, comprising:
a second pinned layer on the bottom electrode, having a second pinned magnetization at the pinned direction;
a second tunneling layer, disposed on the second pinned layer; and
a second magnetic free layer, disposed on the second tunneling layer, having a second free magnetization parallel to the easy axis;
a top electrode, connecting the first free layer and the second free layer; and
wherein the included angle between the pinned direction and the easy axis is substantially 45 or 135 degrees,
wherein a magnetic field sensing direction is perpendicular to the easy axis on the substrate.

3. The in-plane magnetic field sensor as recited in claim 2, further comprising a metal line route crossing the first MTJ device and the second MTJ device of the magnetic field sensing structure of TMR, wherein the first free magnetization and the second free magnetization at the initial state are set to along the easy axis but mutually anti-parallel by a current flowing in the metal line route to generate magnetic fields parallel to the easy axis but opposite direction, respectively.

4. A 2-axis in-plane magnetic field sensor, comprising:
a substrate and
a first in-plane magnetic field sensor on the substrate, having a first pinned direction and a first easy axis; and
a second in-plane magnetic field sensor on the substrate, having a second pinned direction and a second easy axis, wherein the first easy axis is orthogonal to the second easy axis, and the first pinned direction and the second pinned direction both are parallel to a bisection direction, the bisection direction having an angle of 45 degrees to the first easy axis and the second easy axis, respectively,
wherein the first in-plane magnetic field sensor comprises:
a first magnetic sensing structure of TMR comprising:
a first bottom electrode on the substrate;
a first magnetic tunneling junction (MTJ) device, comprising:
a first pinned layer on the first bottom electrode, having a first pinned magnetization at the first pinned direction;
a first tunneling layer, disposed on the first pinned layer; and
a first magnetic free layer, disposed on the first tunneling layer, having a first free magnetization parallel to the first easy axis and a first included angle formed between the first pinned direction and the first easy axis;
a second MTJ device, comprising:
a second pinned layer on the first bottom electrode, having a second pinned magnetization at the first pinned direction;
a second tunneling layer, disposed on the second pinned layer; and
a second magnetic free layer, disposed on the second tunneling layer, having a second free magnetization parallel to the first easy axis; and
a first top electrode, connecting the first free layer and the second free layer,
wherein the first free magnetization and the second free magnetization at an initial state are parallel to the first easy axis but mutual anti-parallel, and the first included angle between the first pinned direction and the first easy axis is substantially 45 or 135 degrees, wherein a first magnetic field sensing direction is perpendicular to the first easy axis on the substrate,
wherein the second in-plane magnetic field sensor comprises:
a second magnetic sensing structure of TMR comprising:
a second bottom electrode on the substrate;
a third MTJ device, comprising:
a third pinned layer on the second bottom electrode, having a third pinned magnetization at the second pinned direction;
a third tunneling layer, disposed on the third pinned layer; and
a third magnetic free layer, disposed on the third tunneling layer, having a third free magnetization parallel to the second easy axis and a second included angle formed between the second pinned direction and the second easy axis;
a fourth MTJ device, comprising:
a fourth pinned layer on the second bottom electrode, having a fourth pinned magnetization at the second pinned direction;
a fourth tunneling layer, disposed on the fourth pinned layer; and
a fourth magnetic free layer, disposed on the fourth tunneling layer, having a fourth free magnetization parallel to the second easy axis; and
a second top electrode, connecting the third magnetic free layer and the fourth magnetic free layer;
wherein the third free magnetization and the fourth free magnetization at the initial state are parallel to the second easy axis but mutual anti-parallel, and the second included angle between the second pinned direction and the second easy axis is substantially 45 or 135 degrees, wherein a second magnetic field sensing direction is perpendicular to the second easy axis on the substrate.

5. The 2-axis in-plane magnetic field sensors of claim 4, wherein the first in-plane magnetic field sensor further comprises a first metal line route crossing the first MTJ device and the second MTJ device, wherein the first free magnetization and the second free magnetization at the initial state are set along the first easy axis but mutually anti-parallel by a first current flowing in the first metal line route to generate magnetic fields parallel to the first easy axis but opposite direction; and the second in-plane magnetic field sensor further comprises a second metal line route crossing the third MTJ device and the fourth MTJ device, wherein the third free magnetization and the fourth free magnetization at the initial state are set to along the second easy axis but mutually anti-parallel by a second current flowing in the second metal line route to generate magnetic fields parallel to the second easy axis but opposite direction.

6. An out-of-plane magnetic field sensor over a substrate having a magnetic field sensing direction perpendicular to the substrate, comprising:
a groove or bulge structure on the substrate, having a first incline and a second incline, wherein the first incline and the second incline have a same bevel to the substrate and are symmetrically flipped with respect to a medial axle of the groove or bulge structure;
a first magnetic field sensing structure of tunneling magneto-resistor (TMR) formed on the first incline, having a first pinned direction and a first easy axis, comprising:
a first bottom electrode on the first incline;
a first magnetic tunneling junction (MTJ) device, comprising:
a first pinned layer on the first bottom electrode, having a first pinned magnetization at the first pinned direction;
a first tunneling layer, disposed on the first pinned layer; and
a first magnetic free layer, disposed on the first tunneling layer, having a first free magnetization parallel to the first easy axis and a first included angle formed between the first pinned direction and the first easy axis;
a second MTJ device, comprising:
a second pinned layer on the first bottom electrode, having a second pinned magnetization at the first pinned direction;
a second tunneling layer, disposed on the second pinned layer; and
a second magnetic free layer, disposed on the second tunneling layer, having a second free magnetization parallel to the first easy axis; and
a first top electrode, connecting the first magnetic free layer and the second magnetic free layer, wherein the first free magnetization and the second free magnetization at an initial state are parallel to the first easy axis but mutual anti-parallel; and
a second magnetic field sensing structure of TMR formed on the second incline, having a second pinned direction and a second easy axis, comprising:
a second bottom electrode on the first incline;
a third MTJ device, comprising:
a third pinned layer on the second bottom electrode, having a third pinned magnetization at the second pinned direction;
a third tunneling layer, disposed on the third pinned layer; and
a third magnetic free layer, disposed on the third tunneling layer, having a third free magnetization parallel to the second easy axis and a second included angle formed between the second pinned direction and the second easy axis;
a fourth MTJ device, comprising:
a fourth pinned layer on the second bottom electrode, having a fourth pinned magnetization at the second pinned direction;
a fourth tunneling layer, disposed on the fourth pinned layer; and
a fourth magnetic free layer, disposed on the fourth tunneling layer, having a fourth free magnetization parallel to the second easy axis; and
a second top electrode, connecting the third magnetic free layer and the fourth magnetic free layer, wherein the third free magnetization and the fourth free magnetization at the initial state are parallel to the second easy axis but mutual anti-parallel,
wherein the first easy axis and the second easy axis are parallel to the medial axle of the groove or bulge structure, the first bottom electrode of the first magnetic field sensing structure of TMR connects with the second bottom electrode of the second magnetic field sensing structure of TMR, and the first top electrode of the first magnetic field sensing structure of TMR connects with the second top electrode of the second magnetic field sensing structure of TMR.

7. The out-of-plane magnetic field sensor as recited in claim 6, further comprising a metal line route crossing the first and the second MTJ devices of the first magnetic field sensing structure of TMR and the third and the fourth MTJ devices of the second magnetic field sensing structure of TMR, wherein the metal line route is used to apply a current at to generate ampere fields to set the first to fourth free magnetizations of the first and second magnetic field sensing structures of TMR at the initial state, respectively, the first and second free magnetizations of the first magnetic sensing structure of TMR are parallel to the first easy axis but mutual anti-parallel, the third and fourth free magnetizations of the second magnetic sensing structure of TMR are parallel to the second easy axis but mutual anti-parallel.

8. A 3-axis magnetic field sensor, comprising:
a first in-plane magnetic field sensor on a substrate to sense an X magnetic field, having a first magnetic field sensing structure of TMR and having a first pinned direction and a first easy axis, wherein the first easy axis is regarded as a Y-axis; and
a second in-plane magnetic field sensor on the substrate to sense a Y magnetic field, having a second magnetic field sensing structure of TMR and having a second pinned direction and a second easy axis, wherein the second easy axis is regarded as an X-axis,
wherein the first easy axis and the second easy axis are orthogonal, and a bisection direction on the substrate has an angle of 45 degrees to the first easy axis and the second easy axis, respectively,
an out-of-plane magnetic field sensor on the substrate to sense a Z magnetic field, having a medial axle is parallel to the bisection direction.

9. The 3-axis magnetic field sensor as recited in claim 8, wherein the first magnetic field sensing structure of TMR, comprising:
a first bottom electrode on the substrate;
a first MTJ device, comprising:
a first pinned layer on the first bottom electrode, having a first pinned magnetization at the first pinned direction;
a first tunneling layer, disposed on the first pinned layer; and
a first magnetic free layer, disposed on the first tunneling layer, having a first free magnetization parallel to the first easy axis and a first included angle formed between the first pinned direction and the first easy axis;
a second MTJ device, comprising:
a second pinned layer on the first bottom electrode, having a second pinned magnetization at the first pinned direction;
a second tunneling layer, disposed on the second pinned layer; and
a second magnetic free layer, disposed on the second tunneling layer, having a second free magnetization parallel to the first easy axis; and
a first top electrode, connecting the first free layer and the second free layer,
wherein the first free magnetization and the second free magnetization at an initial state are parallel to the first easy axis but mutual anti-parallel, and the first included angle between the first pinned direction and the first easy axis is substantially 45 or 135 degrees, wherein a first magnetic field sensing direction is perpendicular to the first easy axis on the substrate,
wherein the second magnetic field sensing structure of TMR, comprising:
a second bottom electrode on the substrate;
a third MTJ device, comprising:
a third pinned layer on the second bottom electrode, having a third pinned magnetization at the second pinned direction;
a third tunneling layer, disposed on the third pinned layer; and
a third magnetic free layer, disposed on the third tunneling layer, having a third free magnetization parallel to the second easy axis and a second included angle formed between the second pinned direction and the second easy axis;
a fourth MTJ device, comprising:
a fourth pinned layer on the second bottom electrode, having a fourth pinned magnetization at the second pinned direction;
a fourth tunneling layer, disposed on the fourth pinned layer; and
a fourth magnetic free layer, disposed on the fourth tunneling layer, having a fourth free magnetization parallel to the second easy axis; and
a second top electrode, connecting the third magnetic free layer and the fourth magnetic free layer;
wherein the third free magnetization and the fourth free magnetization at the initial state are parallel to the second easy axis but mutual anti-parallel, and the second included angle between the second pinned direction and the second easy axis is substantially 45 or 135 degrees, wherein a second magnetic field sensing direction is perpendicular to the second easy axis on the substrate;
wherein the out-of-plane magnetic field sensor over the substrate having a magnetic field sensing direction perpendicular to the substrate, comprising:
a groove or bulge structure on the substrate, having a first incline and a second incline, wherein the first incline and the second incline have a same bevel to the substrate and are symmetrically flipped with respect to a medial axle of the groove or bulge structure;
a third magnetic field sensing structure of TMR formed on the first incline, having a third pinned direction and a third easy axis, comprising:
a third bottom electrode on the first incline;
a fifth MTJ device, comprising:
a fifth pinned layer on the third bottom electrode, having a fifth pinned magnetization at the third pinned direction;
a fifth tunneling layer, disposed on the fifth pinned layer; and
a fifth magnetic free layer, disposed on the fifth tunneling layer, having a fifth free magnetization parallel to the third easy axis and a first included angle formed between the third pinned direction and the third easy axis;
a sixth MTJ device, comprising:
a sixth pinned layer on the third bottom electrode, having a sixth pinned magnetization at the fourth pinned direction;
a sixth tunneling layer, disposed on the sixth pinned layer; and
a sixth magnetic free layer, disposed on the sixth tunneling layer, having a sixth free magnetization parallel to the third easy axis; and
a third top electrode, connecting the fifth magnetic free layer and the sixth magnetic free layer, wherein the fifth free magnetization and the sixth free magnetization at an initial state are parallel to the third easy axis but mutual anti-parallel; and
a fourth magnetic field sensing structure of TMR formed on the second incline, having a fourth pinned direction and a fourth easy axis, comprising:
a fourth bottom electrode on the second incline;
a seventh MTJ device, comprising:
a seventh pinned layer on the fourth bottom electrode, having a seventh pinned magnetization at the seventh pinned direction;
a seventh tunneling layer, disposed on the seventh pinned layer; and
a seventh magnetic free layer, disposed on the seventh tunneling layer, having a seventh free magnetization parallel to the fourth easy axis and a second included angle formed between the fourth pinned direction and the fourth easy axis;
an eighth MTJ device, comprising:
an eighth pinned layer on the fourth bottom electrode, having an eighth pinned magnetization at the eighth pinned direction;
an eighth tunneling layer, disposed on the eighth pinned layer; and
an eighth magnetic free layer, disposed on the eighth tunneling layer, having an eighth free magnetization parallel to the fourth easy axis; and
a fourth top electrode, connecting the seventh magnetic free layer and the eighth magnetic free layer, wherein the seventh free magnetization and the eighth free magnetization at the initial state are parallel to the fourth easy axis but mutual anti-parallel,
wherein the third easy axis and the fourth easy axis are parallel to the medial axle of the groove or bulge structure, the third bottom electrode of the third magnetic field sensing structure of TMR connects with the fourth bottom electrode of the fourth magnetic field sensing structure of TMR, and the third top electrode of the third magnetic field sensing structure of TMR connects with the fourth top electrode of the fourth magnetic field sensing structure of TMR.

10. The 3-axis magnetic field sensor as recited in claim 9, further comprising a first metal line, a second metal line and a third metal line to respectively set, at the initial state, the first and second free magnetizations are parallel to the first easy-axis but anti-parallel, the third and fourth free magnetizations are parallel to the second easy-axis but anti-parallel, the fifth and sixth free magnetizations are parallel to the third easy-axis but anti-parallel, and the seventh and eighth free magnetizations are parallel to the fourth easy-axis but anti-parallel.

11. A method for fabricating the magnetic field sensing structure, wherein the magnetic field sensing structure is recited in claim 9, comprising proceeding a single step of annealing process to set the first to fourth pinned directions of the first to the fourth magnetic field sensing structures of TMR, simultaneously.

12. The method for fabricating the magnetic field sensing structure according to claim 11, wherein the single step of annealing process comprises:
applying a slantwise field along a direction with an azimuth angle α=π/4 and a zenith angle γ=tan⁻¹(sin β) where the azimuth angle α is an included angle between the bisection direction and the X-axis or the Y-axis, the zenith angle γ is an included angle between the slantwise field and the Z-axis perpendicular to the substrate and the parameter β is the bevel angle of the first incline or the second incline to the substrate.

13. The method for fabricating the magnetic field sensing structure according to 11, wherein the single step of annealing process comprises:
applying dual magnetic fields, simultaneously, by an azimuth field H_{AZ} alone the bisection direction and a zenith field H_{Z} alone the Z-axis, where a relationship of the azimuth field and the zenith field is H_{AZ}=H_{Z} sin β, and the parameter β is the bevel angle of the first incline or the second incline to the substrate.

14. A magnetic field sensing circuit for transferring the sensed magnetic field into electronic signal, comprising:
a first magnetic field sensor as recited in claim 2 or in claim 6;
a second magnetic field sensor with an identical structure to the first magnetic field sensor, wherein the free magnetizations are locked as a zero-field reference by the generated ampere fields of current flowing in the metal route during sensing magnetic field;
a bias voltage unit, having a first output terminal and a second output terminal, wherein the first output terminal is connected to both the bottom electrodes of the zero-field reference and the magnetic field sensor, and the second output terminal providing a constant potential;
a clamp voltage current minor, having a input terminal and a first output terminal and a second output terminal, wherein the input terminal is coupled to the second output terminal of the bias voltage unit to receive the constant potential, and the first output terminal is coupled to the top electrode of the zero-field reference; and
a signal transfer amplifying unit, having a first input terminal, a second input terminal, and an output terminal, wherein the first input terminal is coupled to the second output terminal of the bias voltage unit to receive the constant potential, the second input terminal is coupled to the top electrode of the magnetic field sensor and the second output terminal of the clamp voltage current mirror, and the output terminal outputs an electric signal due to the sensed magnetic field.

15. The magnetic-field sensing circuit as recited in claim 14, wherein the bias voltage unit comprises:
a bias voltage source;
a voltage divider comprising:
four same value of a first, a second, a third and a forth resistors coupled in series between a power voltage source and a ground, wherein the joined node of the second resistor and the third resistor is the second output terminal and a constant potential is half of the power voltage source; and
an operational amplifier, having a first input end, a second input end and an output end serving as the first output terminal of the bias voltage unit, the first input end electrically connected to a joined node of the third and forth resistors, a fifth resistor connected between the output end and the second input end, a sixth resistor connected between the second input end and the bias voltage source,
wherein the potential at the second output terminal is a subtraction of the bias voltage source form the half of the power voltage source.

16. The magnetic-field sensing circuit as recited in claim 14, wherein the clamp voltage current mirror comprises:
a first transistor having a gate and a drain serving as the first output terminal;
a second transistor, having a gate connected to the gate of the first transistor, and having a drain serving as the second output terminal, wherein the zero-field reference current form the first output terminal of the first transistor to the zero-field reference is mirrored to the second transistor and output form the second output terminal; and
an operational amplifier, having the first input end and the second input end and an output end, wherein the output end is electrically connected to the gates of the first and the second transistors, the first input end serve as the input terminal of the clamp voltage current mirror, the second input end electrically connected to the first output terminal of the bias voltage unit;

17. The magnetic field sensing circuit according to claim 14, wherein the signal transfer amplifying unit comprises:
an operational amplifier, having the first input end serving as the first input terminal the second input end serving as the second input terminal and an output end serving as the output terminal, wherein the first input terminal receives the constant voltage from the bias voltage unit, the second input is connected to the output terminal of the clamp voltage current mirror; and
a resistor connected between the second input terminal and the output terminal of the operational amplifier,
wherein the resistor transfers the change of sensing current of the sensed magnetic field from the magnetic field sensor into a voltage variation with amplification, the output voltage of the output terminal is summation of the voltage variation and the constant potential at the first input terminal.
